(19) United States
(12) Patent Application Publication
(10) Pub. No.: US 2006/0113531 A1
(43) Pub. Date: Jun. 1, 2006

(54) Semiconductor component and method for the production thereof

(75) Inventors: Marcus Halik, Erlangen (DE); Hagen Klauk, Stuttgart (DE); Guenter Schmid, Hemhofen (DE); Ute Zschieschang, Stuttgart (DE)

Correspondence Address: SLATER & MATSIL LLP, 17950 PRESTON ROAD, SUITE 1000, DALLAS, TX, 75252, US

(73) Assignee: Infineon Technologies AG

(21) Appl. No.: 11/329,695

(22) Filed: Jan. 11, 2006

Related U.S. Application Data
(63) Continuation of application No. PCT/DE04/01515, filed on Jul. 12, 2004.

(30) Foreign Application Priority Data
Jul. 11, 2003 (DE) 103 32 567.0

(51) Int. Cl. H01L 29/08

(52) U.S. Cl. 257/40; 430/296

(57) ABSTRACT

An embodiment of the invention provides a semiconductor component and method of forming thereof. The component comprises a dielectric layer over a substrate, and a layer of an organic compound covalently bonded to the dielectric layer. The organic compound has a chemical functionality selected from the group consisting essentially of a silicon-halogen, a silicon-alkoxy group, an amino group, an amide group, a reactive carboxylic acid derivative, a chloride ester, or an ortho ester. The organic compound may further include a polar chemical functionality that induces a dipole moment in the organic compound. The organic compound may be arranged as a monolayer on the dielectric layer. An organic semiconducting layer is formed on the layer of the organic compound.

This application is a continuation of co-pending International Application No. PCT/DE2004/001515, filed Jul. 12, 2004, which designated the United States and was not published in English, and which is based on German Application No. 103 32 567.0, filed Jul. 11, 2003, both of which applications are incorporated herein by reference in their entirety.

### TECHNICAL FIELD

This invention relates generally to semiconductor manufacturing and more particularly to organic field effect transistors (OFET) and also to controlling threshold voltage shift in OFET.

### BACKGROUND

Organic field effect transistors (OFET) based on organic semiconductor layers are of interest for electronic applications that require low production costs, flexible or unbreakable substrates, or the fabrication of transistors and integrated circuits over large active areas. By way of example, organic field effect transistors are suitable as pixel control elements in active matrix screens or for the production of extremely inexpensive integrated circuits such as are used, for example, for the active labeling and identification of merchandise and goods, but also for future control circuits of organic memory elements.

Transistors and integrated circuits (ICs) based on organic semiconductor layers currently operate to the greatest possible extent using p-MOS technology, since essentially only organic p-type semiconductors are stable enough to produce durable devices.

Most of the previously known organic semiconductors (e.g. pentacene, tetracene, oligothiophenes and polythiophenes), which are also taken into consideration for applications from the standpoint of their charge carrier mobility, usually have a slightly positive threshold voltage (Vth) in transistors, that is to say that the transistors still do not switch off completely when there is a potential of 0 V at the gate electrode. The consequence of this is that simple inverters (two transistors) do not show the correct logical function and ring oscillators based thereon do not oscillate.

This problem has been solved hereto in terms of circuitry in such a way that inverters and circuits resulting therefrom are produced with an integrated level shift. The consequence of this additional correction of the logical function is that the number of transistors for a functional inverter is doubled from two to four such as described by H. Klauk, D. J. Gundlach, T. N. Jackson IEEE Electron Device Letters, 1999, 20, 289-291. Moreover, a further supply voltage is required for the level shifter.

Approaches exist for setting the threshold voltage through the choice of a suitable gate dielectric (inorganic or organic) such as described by H. Klauk, M. Halik, U. Zschieschang, G. Schmid, W. Radlik, W. Weber Journal of Applied Physics, 2002, 92, 5259-5263. It has been found in this case, however, that values in the negative range (approximately −8 V) were reached, but the fluctuations of these values are relatively large (±10 V) and so a reliable circuit design for ICs is not possible at the present time. In addition, although it is described that a monolayer of octadecyltrichlorosilane (OTS) in the case of SiO₂ as gate dielectric in pentacene transistors brings about a shift in the threshold voltage by a few volts compared with bare SiO₂ as gate dielectric, this is not effected in such a way that a systematic and primarily defined setting of the threshold voltage can be performed.

A third possibility consists in the dynamic operation of a circuit. In this case, a circuit system is activated by application of an external pulse voltage as described by W. Fix, A. Ullmann, J. Ficker, W. Clemens Applied Physics Letters, 2002, 81, 1735-1737. This is possible in principle for simple demonstrator circuits, but very complicated for more complex logic circuits.

### SUMMARY OF THE INVENTION

These and other problems are generally solved or circumvented, and technical advantages are generally achieved by preferred embodiments of the present invention that provide methods and structures for organic field effect transistors (OFET).

An embodiment of the invention provides a semiconductor component. The component comprises a dielectric layer over a substrate, and a layer of an organic compound covalently bonded to the dielectric layer. Preferably, the organic compound has a chemical functionality (i.e., a functional group) selected from the group consisting essentially of a silicon-halogen, a silicon-alkoxy group, an amino group, an amide group, a reactive carboxylic acid derivative, a chloride ester, or an ortho ester. The organic compound may further include a polar chemical functionality that induces a dipole moment in the organic compound.

Another embodiment of the invention provides an organic field effect transistor (OFET). The OFET comprises a gate electrode layer, a gate dielectric layer adjacent the gate electrode layer, and a threshold voltage (Vth) setting layer adjacent the gate dielectric layer. Preferably, wherein the Vth setting layer includes an organic compound have at least one anchor group capable of bonding to the gate dielectric layer. The organic compound may further comprise at least one polar group. The OFET preferably further comprises an organic semiconducting layer on the Vth setting layer.

Another embodiment of the invention provides a method of forming a semiconductor component. The method comprises forming a dielectric layer on a substrate and depositing an organic layer on the dielectric layer. Preferably, the organic layer includes at least one compound represented by the chemical formulas KBM, APTS, or AAPTS. The organic layer also comprise at least one of a polyvinylpyrrolidone, a pyridilinone, or block copolymers thereof.

### BRIEF DESCRIPTION OF THE DRAWINGS

The invention is explained in more detail below using a plurality of exemplary embodiments with reference to the figures of the drawings, in which:

FIG. 1 shows a cross-sectional view of an OFET according to embodiments of the invention;

FIG. 2 shows a schematic illustration of a layer structure with an organic threshold voltage (Vth) setting compound according to embodiments of the invention;

FIGS. 3a-c show structural formulas of Vth setting compounds according to embodiments of the invention;

FIG. 4a shows measurement results of the threshold voltage as a function of the Vth setting compound according to embodiments of the invention; and

FIG. 4b shows a correlation of the measured threshold voltage with the dipole moment according to embodiments of the invention;

Table 1 shows threshold voltage for OFETs having Vth controlling layers according to embodiments of the invention.

The following list of reference symbols can be used in conjunction with the figures:
1 Anchor group
2 Polar group
10 Layer for the targeted setting of the threshold voltage by means of electrostatic interaction
20 Base substrate for OFET
21 Gate electrode
22 Gate dielectric layer
23a Source layer
23b Drain layer
24 Active semiconductor layer
25 Passivation layer

### DETAILED DESCRIPTION OF ILLUSTRATIVE EMBODIMENTS

The making, operation, and fabrication of the presently preferred embodiments are discussed in detail below. However, the embodiments and examples described herein are not the only applications or uses contemplated for the invention. The specific embodiments discussed are merely illustrative of specific ways to make and use the invention, and do not limit the scope of the invention or the appended claims.

Exemplary materials, structures, and methods are provided below for fabricating a semiconductor device. In a preferred embodiment of the invention, the semiconductor device includes an organic field effect transistor (OFET). Although the exemplary embodiments are described as a series of steps, it will be appreciated that this is for illustration and not for the purpose of limitation. For example, some steps may occur in a different order than illustrated yet remain within the scope of the invention. Also, not all illustrated steps are necessarily required to implement the invention.

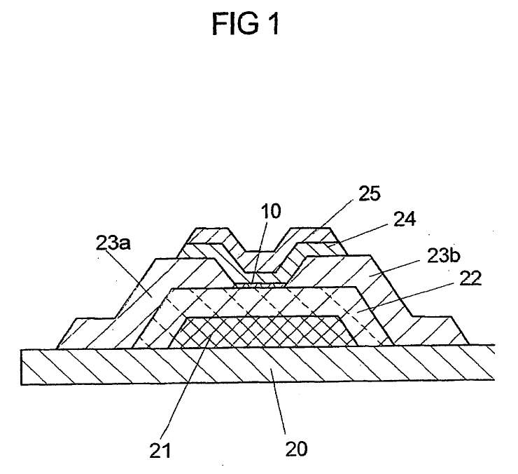

Turning now to FIG. 1, there is illustrated a schematic, cross sectional view of an organic field effect transistor (OFET). Organic field effect transistors are electronic devices comprising a plurality of layers (or films), which are preferably patterned in order to generate integrated circuits by connecting individual layers. In an embodiment, FIG. 1 shows the basic construction of such a transistor in a bottom-contact architecture.

A gate electrode 21 is arranged on a base substrate 20, said gate electrode being covered by a gate dielectric layer 22. The gate dielectric layer 22 preferably has a layer thickness of less than about 5 nm.

A threshold voltage (Vth) setting layer 10 is arranged in a region on the gate dielectric layer 22. The gate dielectric layer 22 preferably forms a substrate for the layer for setting the threshold voltage 10. The Vth setting layer 10 is connected toward the top to an active semiconducting layer 24. The active semiconducting layer 24 preferably comprises an organic semiconductor such as pentacene. A source layer 23a and a drain layer 23b are arranged laterally, both of which are likewise connected to the overlying active semiconducting layer 24. A passivation layer 25 is arranged above the active semiconducting layer 24.

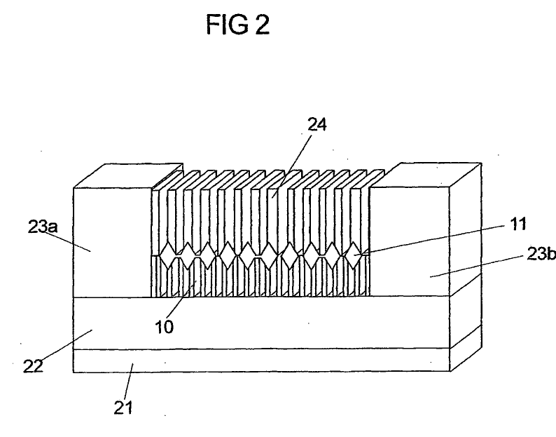

The region of the charge carrier channel in the OFET in accordance with FIG. 1 is illustrated in enlarged fashion in FIG. 2. A plurality of rhombi 11 symbolize the electrostatic interactions between the Vth setting layer 10 and the overlying active layer 24.

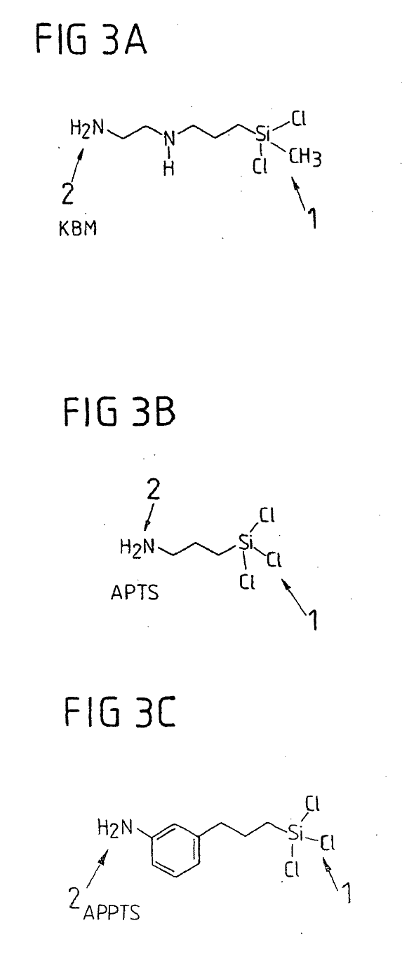

FIGS. 3a to 3c illustrate chemical structures of compounds used to form the Vth setting layer 10. Each of three preferred compounds KBM, FIG. 3a; APTS, FIG. 3b; and APPTS, FIG. 3c include an anchor group 1. The anchor group 1, preferably comprises a silane group. In other embodiments, the compounds used to form the Vth setting layer 10 may comprise a polyvinylpyrrolidone, a pyridilinone, or statistical or block copolymers that contain these units.

With the anchor group 1, the compound used to form the Vth setting layer 10 can form a bond with a substrate, which preferably comprises the dielectric layer 22 in FIG. 2. On account of the essentially linear character of three preferred compounds, KBM, APTS, APPTS, monolayers of the compounds advantageously form on the dielectric layer 22. Within the monolayers, the longitudinal axes of the compound used to form the Vth setting layer 10 are oriented parallel to one another and perpendicular to the dielectric layer 22. As shown in FIGS. 3a-3c, the compounds used to form the Vth setting layer 10 have a group for producing a dipole moment 2, preferably at the ends of the compound and opposite to the anchor group 1.

Preferably, at least one anchor group 1 may be covalently bonded to a dielectric layer. It is particularly preferred if at least one anchor group 1 is a silicon-halogen group, a silicon-alkoxy group, an amino group, an amide group or a reactive carboxylic acid derivative,sa chloride, or an ortho ester. It is further preferable if, the group for producing a dipole moment 2 has a polar group, more preferably an amino group, a cyano group, a nitro group, or a ferrocenyl group. Preferred polar groups may include atoms that have a free pair of electrons such as oxygen, nitrogen, sulfur, and/or phosphorus.

In embodiments of the invention, the formation of monolayers is facilitated if the compound used to form the monolayers is structurally essentially in a linear fashion or has a long axis in comparison with other groups of the compound. In addition, it is advantageous particularly, for monolayers if the anchor group 1 and the group having the dipole moment 2 (or the group having a free pair of electrons) are arranged at opposite ends of the linear compound. It is particularly advantageous if a part of the compound has an increased affinity for the surface of the substrate, in particular a dielectric layer, and in that there is arranged at the opposite end of the compound a group with high packing density, which is inert with respect to the substrate.

Preferably, the chemical compound is intended to be applied such that it is as thin as possible, and more preferably as a monolayer, and inexpensively. Preferably, it is fixed chemically in the channel (covalently bonded to the dielectric) in order to avoid diffusion processes. Through the type of chemical compound, the value for the threshold voltage is adjusted to obtain an optimum settable value of the threshold voltage for the respective application.

Continuing with FIG. 2, a monolayer is formed using at least one of KBM, APTS and APPTS, thereby forming the Vth setting layer 10. The Vth setting layer 10 according to embodiments of the invention advantageously interacts electrically with the overlying semiconductor layer 24. Such a preferred interaction advantageously changes the semiconducting properties such that the threshold voltage is affected in a targeted manner. In preferred embodiments of the invention, Vth is lowered.

While not intending embodiments of the invention to be limited by any proposed theory of operation, an effect according to the invention is based on the fact that the introduced compound first of all closes charge carrier sinks (traps) and at the same time forms a macroscopic effect as a result of the high order thereof the molecular properties of the molecules (dipole moment), said effect having a favorable influence on the electrochemical and electrical properties of an e.g. overlying organic semiconductor layer and the morphology. If the compound has the ability to form monomolecular layers on the substrate, in particular a dielectric layer, semiconductor components can be constructed from layers in a simple manner.

Embodiments of the invention advantageously have the effect that the number of transistors for a logic circuit be almost halved, and so in addition, fewer interconnects and vias are required and, following from this, the required area for the circuit becomes smaller. Furthermore, the yield should be increased. The second supply voltage for the level shifter is likewise obviated. This modification is effected chemically in such a way that a chemical compound that influences the electrical properties of the organic semiconductor upon application of a voltage is introduced or applied into the channel of the transistor (path on the dielectric between source and drain electrode) prior to the deposition of the organic semiconductor.

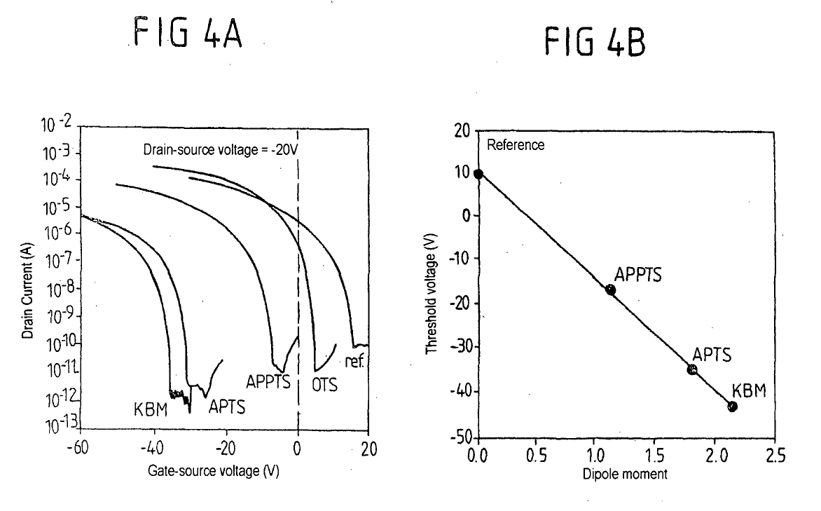

Turning now to FIGS. 4a and 4b and Table 1, an advantage of the Vth setting layer 10 formed according to embodiments of the invention layer 10 may be applied inexpensively to the transistor structure (prior to the deposition of the organic semiconductor layer). An embodiment of the invention comprises a method of forming an OFET. In preferred embodiments of the invention, the OFET includes a Vth setting layer 10 formed using an organic compound.

In an embodiment, a method comprises a dipping process, which may include dipping a substrate into a dilute solution of between about 0.1 and about 1% KBM, APTS or APPTS. The molecules bind to the dielectric layer 22 with their anchor group 1. By way of example, a chloro- or alkosysilane binds selectively to a surface functionalized with OH groups to form an Si—O bond. Rinsing with a pure solvent may remove any excess material from the substrate. The threshold voltage can be suppressed in a particularly targeted manner if the compound has one of the structures correspoding to KBM, APTS or APPTS as shown in FIGS. 3a-3c.

In an alternative embodiment of the invention, the method may comprise using vapor phase deposition to form Vth setting layer 10. In an embodiment, the compounds illustrated in FIGS. 3a to 3c are preferably applied as a monolayer from the vapor phase onto a substrate. In an embodiment, the substrate comprises doped, thermally oxidized (100 nm SiO₂) silicon wafers. A 30 nm thick layer 24 of an organic semiconductor, preferably pentacene, is subsequently vapor-deposited. Completing the transistor construction may comprise forming source and drain contacts (23a, 23b) such as by vapor-depositing a 30 nm thick gold layer (patterning is effected by application of a shadow mask). Afterward, the transistors are characterized electrically.

To illustrate advantages provided by embodiments of the invention, a conventional (or reference) OFET and OFETs according to embodiments of the invention were fabricated and their electrical characteristics measured. A coating with OTS was also effected for comparison purposes.

The results of the measured threshold voltages are illustrated in Table 1 and FIG. 4a. The correlation of the measured threshold voltages with the dipole moment of the respective compound is shown in FIG. 4b. Results demonstrate that the threshold voltage may be set in a targeted manner depending on the compounds used to form the Vth setting layer 10. The threshold voltages are correlated with molecular properties (such as dipole moment) and layer properties (such as free surface energy). It is clearly evident that the threshold voltage is significantly reduced by comparison with the reference (no separate layer) and also by comparison with OTS.

Embodiments of the invention advantageously provide a simplified OFET and its method of fabrication. Embodiments provide for the chemical modification of the dielectric surface and thus of the charge carrier channel. Embodiments replace the previously required solution to the problem of the positive threshold voltages in OFETs by means of level shift thereby saving approximately 50% of the transistors required per circuit.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

TABLE 1

| SAM material | Vₜₕ[V] |
|---|---|
| No SAM (reference) | 2 |
| OTS | −1 |
| APPTS | −17 |
| APTS | −35 |
| KBM | −43 |

What is claimed is:

1. A semiconductor component comprising:
a dielectric layer over a substrate; and
a layer of an organic compound covalently bonded to the dielectric layer.

2. The semiconductor component of claim 1, wherein the semiconductor component is an organic field effect transistor.

3. The semiconductor component of claim 1, wherein the organic compound comprises a chemical functionality selected from the group consisting essentially of a silicon-halogen, a silicon-alkoxy group, an amino group, an amide group, a reactive carboxylic acid derivative, a chloride ester, or an ortho ester.

4. The semiconductor component of claim 3, wherein the organic compound further comprises a polar chemical functionality selected from the group consisting essentially of an amino group, a cyano group, a nitro group, or a ferrocenyl group.

5. The semiconductor component of claim 3, wherein the organic compound further comprises a chemical functionality having a free pair of electrons.

6. The semiconductor component of claim 5, wherein the chemical functionality comprises at least one of oxygen, nitrogen, sulfur, and phosphorus.

7. The semiconductor component of claim 1, wherein the organic compound is arranged substantially in a monolayer on the dielectric layer.

8. The semiconductor component of claim 1, wherein the organic compound has an essentially linear structure.

9. The semiconductor component of claim 8, wherein a first end of the linear structure is covalently bonded to the dielectric layer and an opposite end of the linear structure includes a polar chemical functionality.

10. The semiconductor component of claim 9, wherein the first end of the linear structure has an increased affinity for the dielectric layer, and the opposite end of the linear structure has a high packing density, the opposite end being inert with respect to the substrate.

11. The semiconductor component of claim 1, wherein the organic compound comprises one of the following chemical formulas KBM, APTS, or AAPTS:

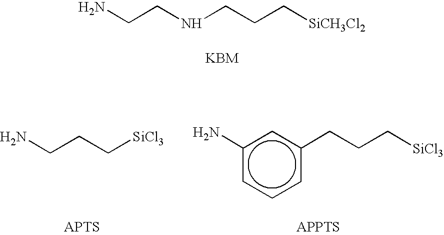

12. The semiconductor component of claim 1, wherein the organic compound is selected from the group consisting essentially of a polyvinylpyrrolidone, a pyridilinone, or a copolymer thereof.

13. An organic field effect transistor (OFET) comprising:
a gate electrode layer;
a gate dielectric layer adjacent the gate electrode layer;
a threshold voltage (Vth) setting layer adjacent the gate dielectric layer, wherein the Vth setting layer includes an organic compound have at least one anchor group capable of bonding to the gate dielectric layer and at least one polar group; and
an organic semiconducting layer on the Vth setting layer.

14. The organic field effect transistor of claim 13, wherein the anchor group covalently bonds to the gate dielectric layer.

15. The organic field effect transistor of claim 13, wherein the anchor group consists essentially of a silicon-halogen group, a silicon-alkoxy group, an amino group, an amide group, a chloride ester, and an ortho ester.

16. The organic field effect transistor of claim 13, wherein the polar group consists essentially of an amino group, a cyano group, a nitro group, or a ferrocenyl group.

17. The organic field effect transistor of claim 13, wherein the organic compound is arranged substantially in a monolayer on the gate dielectric layer.

18. The organic field effect transistor of claim 13, wherein the organic compound comprises at least one of the following chemical formulas KBM, APTS, or AAPTS:

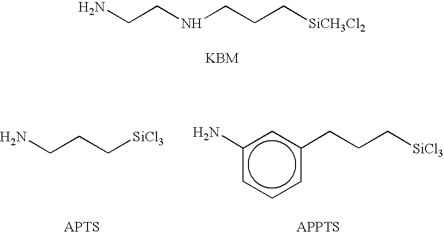

19. The semiconductor component of claim 13, wherein the organic compound is selected from the group consisting essentially of a polyvinylpyrrolidone, a pyridilinone, or a copolymer thereof.

20. A method of forming a layer on a semiconductor component, the method comprising:
forming a dielectric layer on a substrate; and
depositing an organic layer on the dielectric layer, wherein the organic layer includes at least one compound represented by the chemical formulas KBM, APTS, or AAPTS:

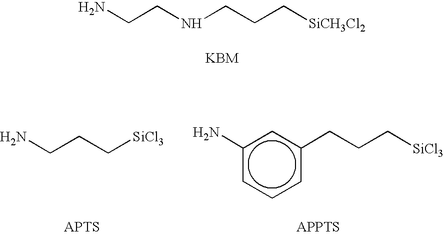

21. The method of claim 20, wherein the depositing comprises a process selected from the group consisting essentially of vapor phase deposition, and dipping the substrate into a solution of the compound.

22. The method as claimed in claim 21, wherein the concentration of the compound in the solution is between about 0.1 and about 1%.
